(19) United States
(12) Patent Application Publication
(10) Pub. No.: US 2013/0083928 A1
(43) Pub. Date: Apr. 4, 2013

(54) SPEAKER TEMPERATURE CONTROL

(71) Applicants: Joseph M. Williams, Morgan Hill, CA (US); Andrew P. Bright, San Francisco, CA (US)

(72) Inventors: Joseph M. Williams, Morgan Hill, CA (US); Andrew P. Bright, San Francisco, CA (US)

(73) Assignee: Apple Inc., Cupertino, CA (US)

(21) Appl. No.: 13/364,982

(22) Filed: Feb. 2, 2012

Related U.S. Application Data
(60) Provisional application No. 61/541,937, filed on Sep. 30, 2011.

(51) Int. Cl. H03G 11/00

(52) U.S. Cl. 381/55

(57) ABSTRACT

A method for controlling an audio signal that is driving a speaker is as follows. A sequence of estimated temperatures are computed, using a speaker thermal model, as a function of an audio signal that is driving the speaker. In addition, a sequence of attenuation values are computed, as a function of the estimated temperatures sequence, using an excess variable. The excess variable is defined as a difference between an estimated temperature and a thermal limit of the speaker. The audio signal is then attenuated in accordance with the sequence of attenuation values. Other embodiments are also described.

### RELATED MATTERS

This application claims the benefit of the earlier filing date of provisional application No. 61/541,937, filed Sep. 30, 2011, entitled “Speaker Temperature Control”.

### BACKGROUND

Speakers have relatively low efficiency in the conversion of an electrical audio input signal into mechanical or acoustical output (sound waves). Most of the input energy is used to heat up a voice coil that moves a diaphragm to produce the sound waves. Although some materials may operate at relatively high temperatures, including certain permanent magnet materials that are used in the magnet system of the speaker, excessive temperature can result in damaging the speaker. In addition, certain characteristics of audio signals can also lead to increased or even excessive temperature in a speaker. When a speaker is producing a high volume of sound for an extended amount of time, the amount of power being dissipated may rise to a sufficiently high level that causes the speaker to rise to very high temperatures thereby putting the speaker at risk for damage by overheating. Typically, the risk of heat damage rises when continuously high levels of sound are being produced for a fairly long period of time, rather than in response to sharp spikes. It is possible to limit the amplitude of the audio signal that is driving the speaker, namely by attenuating the signal or reducing the gain applied to it appropriately, based on, for instance, the speaker's nominal power rating and impedance. A simple RMS voltage limiter, however, neglects the fact that a speaker can usually handle large RMS voltages for sufficiently short periods of time, so that approach is likely to provide too much limiting. Another approach is to monitor the voltage and current that is being delivered by the power amplifier to the speaker. In yet another solution, a detailed thermal model of a speaker is defined, and is then used to continuously calculate an estimate of the temperature of, for instance, the speaker voice coil, as the input audio signal is also applied to the voice coil.

The thermal model approach may track the voltage that is being applied to the terminals of a speaker, and then uses the measured voltage to calculate or predict the instantaneous temperature of, for instance, the voice coil. As the estimated temperature varies and crosses predefined thresholds, a control algorithm responds by varying the gain (attenuation) that is applied to the audio signal in order to prevent the speaker from overheating.

### SUMMARY

An embodiment of the invention is a method for controlling or limiting a temperature of a speaker, as well as a hardware apparatus for doing so. An embodiment of the invention may be able to protect the speaker while attempting to reduce the amount of attenuation that is applied to an audio input signal that is driving the speaker, so as to limit the temperature but without reducing the sound output unnecessarily. A thermal model of the speaker is defined that computes an estimated or predicted temperature of the speaker, based on the input audio signal. Based on the estimated temperature, the audio signal is then attenuated in a particular manner, so as to preferably reduce or even minimize any unnecessary attenuation, reduce or even minimize any overshoot of the estimated temperature (that is beyond a thermal limit defined for the speaker), and cause the estimated temperature (when it is in excess of the thermal limit) to quickly settle to the thermal limit.

In accordance with an embodiment of the invention, a process for controlling the temperature of a speaker (also referred to as a loudspeaker) proceeds as follows. While the estimated temperature is less than a certain percentage of a predefined thermal limit (e.g., 80% or 90%), no attenuation is applied (that is, the gain is essentially zero dB). In other words, while the estimated temperature is below this “soft limit”, no attenuation is applied. If, however, the estimated temperature rises into a soft limit range (between the soft limit and the thermal limit), then the audio signal is attenuated by a factor that may be a function of the square root of a polynomial, where the polynomial is a function of a variable referred to as the “excess”, namely the difference between the estimated temperature and the thermal limit. When the estimated temperature rises above the thermal limit, the attenuation becomes a function of a summation of several prior samples of the excess variable. This may help reduce any overshoot of the estimated temperature, i.e. above the thermal limit.

In another embodiment, the summation term is retained when computing the current attenuation setting, even though the estimated temperature is dropping into the soft limit range, because the estimated temperature is oscillating between the soft limit range and above the thermal limit. Here, the excess variable becomes negative in the soft limit range, thereby steadily reducing the impact of the summation term (so long as the estimated temperature remains in the soft limit range). This tends to reduce the severity of the gain reduction, which is desirable since the speaker is still operating below its thermal limit. This is contrast to the case where the estimated temperature is rising into the soft limit range, in which case the summation term is not used to compute the next attenuation update.

In yet another embodiment, the estimated temperature is varying yet settling within the soft limit range. Here, provided that the derivative of the estimated temperature is below a given threshold, the attenuation is slowly reduced (or gain is slowly added back) so as to not unnecessarily attenuate the audio signal while the speaker is operating below the thermal limit.

The above summary does not include an exhaustive list of all aspects of the present invention. It is contemplated that the invention includes all systems and methods that can be practiced from all suitable combinations of the various aspects summarized above, as well as those disclosed in the Detailed Description below and particularly pointed out in the claims filed with the application. Such combinations have particular advantages not specifically recited in the above summary.

### BRIEF DESCRIPTION OF THE DRAWINGS

The embodiments of the invention are illustrated by way of example and not by way of limitation in the figures of the accompanying drawings in which like references indicate similar elements. It should be noted that references to “an” or “one” embodiment of the invention in this disclosure are not necessarily to the same embodiment, and they mean at least one.

FIG. 1 is a block diagram of relevant components of an audio device in which a thermal control module for a speaker may be implemented.

FIG. 2 is an example block diagram of a thermal control module.

FIG. 3 shows simulation plots of gain and predicted temperature generated by the thermal control module, for an example input audio signal.

FIG. 4 shows simulation plots of gain and predicted temperature by the thermal control module, for a full-scale square wave input signal with a pause.

FIG. 5 shows simulated plots of several variables with respect to time, including predicted temperature, calculated gain, and derivative of temperature.

FIG. 6 shows a scenario where the estimated temperature oscillates around the thermal limit, and also indicates several samples of the excess variable.

### DETAILED DESCRIPTION

Several embodiments of the invention with reference to the appended drawings are now explained. While numerous details are set forth, it is understood that some embodiments of the invention may be practiced without these details. In other instances, well-known circuits, structures, and techniques have not been shown in detail so as not to obscure the understanding of this description.

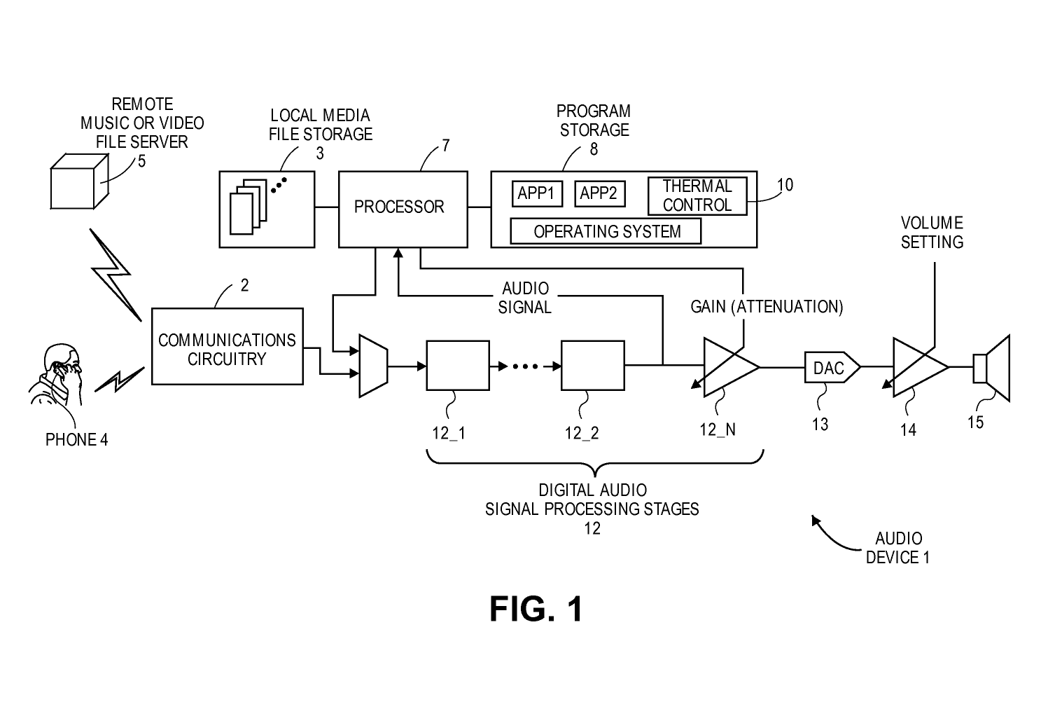

FIG. 1 is a block diagram of relevant components of an audio device in which a thermal control module for a speaker may be implemented. The audio device 1 may be a consumer electronic audio output device such as a desktop computer, a notebook or laptop computer, a tablet computer, or a smart phone. The source of the audio signal (that will be converted to sound through a speaker 15) may be communications circuitry 2 which receives the audio signal in the form of a downlink communications signal from a remote music or video file server 5 (e.g., a music or video stream over the Internet). The audio signal may alternatively contain speech from a phone 4 of a far-end user that is engaged in a two-way voice communications session with a near-end user (not shown) of the audio device 1. The session in that case may be generically referred to as a voice call, and it may also live video transfer such as in a video call. As yet another possibility, the audio signal may be originated by a processor 7 reading a music or video file, where the file may be stored in a local media file storage 3 within a housing (not shown) of the audio device 1, or it may be stored in another device in the same local area network as the audio device 1. The processor 7 may be programmed in accordance with an operating system and one or more application programs (e.g., app1, app2), which are stored in a program storage 8, typically also located within the housing of the audio device 1. The local media file storage 3 and program storage 8 may be implemented as machine-readable media such as non-volatile solid-state memory (e.g., flash memory, rotating magnetic disk drive, or a combination thereof). The processor 7, in this case, is also programmed in accordance with, or is to execute, instructions (program code and data) within a thermal control module 10. The thermal control module 10 as described below defines the operations of a process for controlling a temperature of the speaker 15 during audio playback.

The selected audio signal, which in this case is in digital form, is provided to a group of audio signal processing stages 12. Depending on the source or type of signal, the signal processing stages 12 may vary, so as to enhance the quality of the sound that is ultimately produced through the speaker 15. These stages may include one or more of the following: automatic gain control, noise reduction, equalization, acoustic echo cancellation, and compression or expansion. Most of these stages are expected to be linear and hence their order is immaterial; however, in some cases there may be a non-linear operation, such as limiting, in which case the order may be of consequence. Depicted here as the last stage, there is a gain/attenuation stage 12_N which may attenuate the audio signal in order to control or limit a temperature of the speaker 15. Note, however, that because the gain stage 12_N is a linear operation, it need not be in the last position shown.

Once all of the desired digital signal processing has been performed upon the audio signal, which at this point is a discrete time sequence, the signal is converted into analog form by a digital-to-analog converter (DAC) 13. The resulting analog or continuous time signal is then amplified by an audio power amplifier 14, in accordance with a volume setting that may be selected by a user of the audio device 1. The output of the power amplifier 14 drives the speaker 15, and in particular a voice coil of the speaker 15, which in turn converts the audio signal into sound waves.

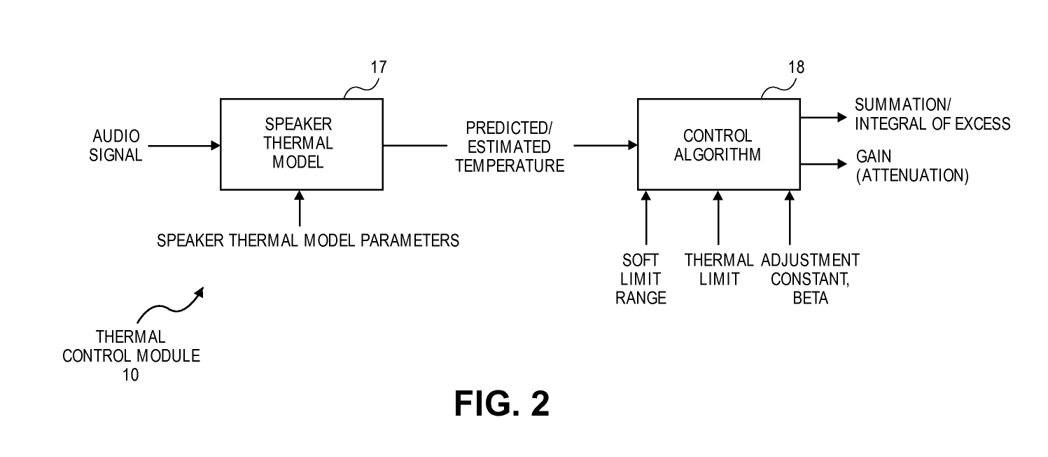

As explained above in the Background section, certain characteristics of audio signals, including their frequency content, as well as the volume setting for their playback, may lead to increased or even excessive temperature in the speaker 15, which may result in damaging the speaker or creating other difficulties for components that may be close to the speaker 15 (within the housing of the audio device 1). A thermal control module 10 is described here, as shown in FIG. 2, which may be able to sufficiently control or limit the temperature, while reducing unnecessary attenuation of the audio signal and also reducing overshoot of the temperature above a thermal limit of the speaker. The thermal control module 10 may be implemented as a programmed processor, such as the processor 7, or it may be implemented entirely as hardwired logic. The thermal control module 10 is shown in FIG. 1 as software (e.g., as part of the operating system's audio hardware abstraction layer), but it may alternatively be viewed as a hardware component.

The thermal control module includes a speaker thermal model 17, which generates a predicted or estimated temperature of the speaker 15, based on an input digital audio sequence. The model 17 has several speaker thermal model parameters that may be defined in a laboratory test setting, based on the physical characteristics and input power handling capability of the speaker 15 and the way in which the speaker 15 is housed. These parameters take into account that the voice coil in the speaker 15 may heat up and cool down fairly quickly, particularly when the speaker 15 is relatively small, such as ones that are used in consumer electronic devices. The parameters used by the thermal model 17 may include thermal time constants of the voice coil and those of the magnet system and frame, thermal resistance between the coil and the magnet system, and thermal resistance between the magnet system and the ambient air outside of the audio device 1. In some instances, the estimated temperature that is computed by the thermal model is a voice coil temperature, although a thermal model that predicts a different estimated temperature, e.g. that of the magnet system or the frame, may also be used. Note that the estimated or predicted temperature may alternatively be a combination that represents, for instance, an overall temperature for the speaker, as opposed to just that of a specific location such as the voice coil or the magnet system. The thermal model 17 may also be fairly complex and include several state variables and electromechanical parameters, as well as thermal parameters and audio signal parameters, including the volume setting and characteristics of the power amplifier.

The output of the speaker thermal model 17 is a predicted or estimated temperature sequence whose sample rate may also be designed, based on the thermal time constants for instance, to yield the desired ultimate effect on the temperature of the speaker 15. The estimated temperature sequence is then fed to a control algorithm 18 which then, based on several predefined parameters including a thermal limit, a soft limit range and an adjustment constant (beta), will calculate a gain (attenuation) setting for the gain stage 12_N (see FIG. 1).

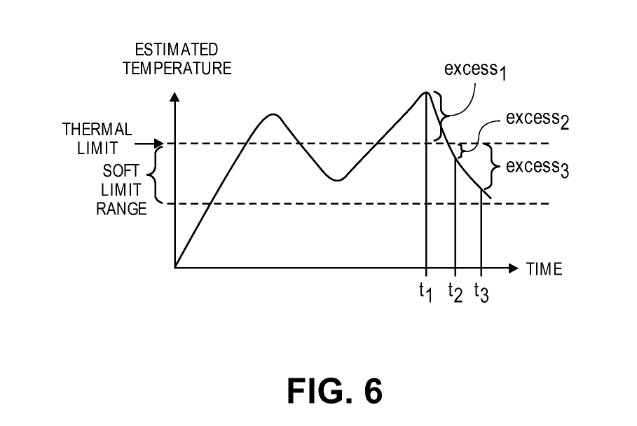

In addition, the control algorithm 18 computes a summation or integral of a variable referred to as “excess”, which may be defined as a difference between an estimated temperature value (or sample) and the thermal limit. Referring to FIG. 6, this figure shows an example waveform of the estimated temperature, albeit in the form of a continuous-time signal, as a function of time. It shows how the estimated temperature may rise above the thermal limit and then return into a soft limit range, before rising up again past the thermal limit and then dipping back into the soft limit range. Note each instance of the excess variable, where excess₁ is a positive value while excess₂ and excess₃ are negative values. As an example, the thermal limit may be 100 degrees C., and the soft limit range may be defined as the range between a soft limit, e.g. a percentage of the thermal limit, and the thermal limit itself. With these variables having been defined, additional details of the control algorithm 18 may now be described.

A first version of the thermal control algorithm 18 may be described as follows:

$$if ( estimated\_temp > thermal\_limit )$$

$$gain = \sqrt{{K}_{1} - {K}_{2} \times \frac{excess}{soft\_limit \_range}} - \frac{beta}{soft\_limit \_range} {\sum }_{i = 1}^{N} {excess}_{i}$$

$$else if ( estimated\_temp > 80 \% * thermal\_limit )$$

$$gain = \sqrt{{K}_{3} - {K}_{4} \times \frac{excess}{soft\_limit \_range}}$$

$$else do nothing$$

As seen above, when the estimated temperature is above the thermal limit, the gain (attenuation) is primarily given by the square root function of the variable excess, where excess may be defined as the difference between the current sample of the estimated temperature and the thermal limit, and soft_limit_range is as defined in FIG. 6. The argument of the square root includes a polynomial in excess, and in this case a first order polynomial. The constants K₁, K₂ and the constant scaling factor beta may be selected to tune the gain equation for the particular speaker 15, to achieve the desired attenuation. In one instance, K₁=0.75 and K₁=0.5 and beta=0.5.

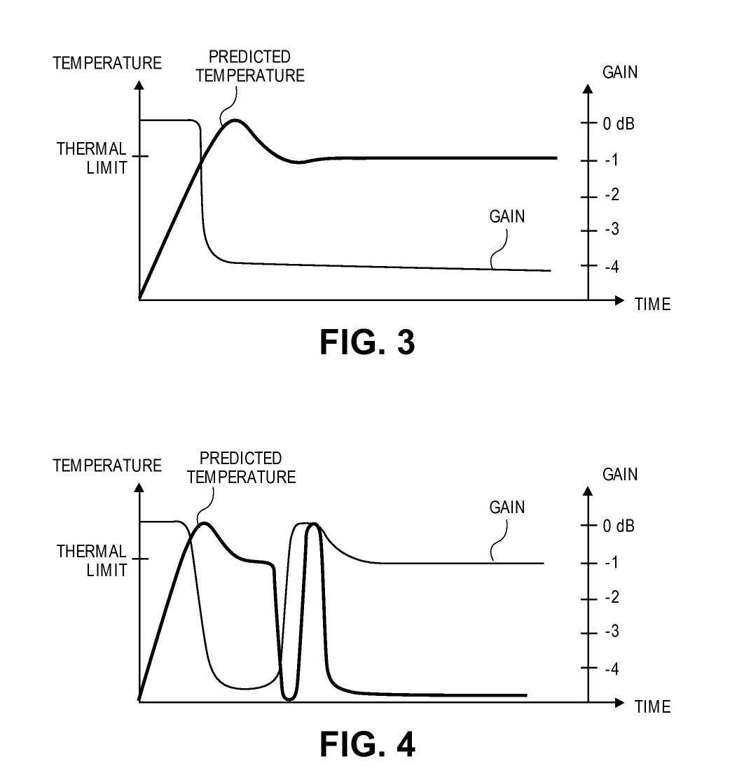

The basic gain equation of the control algorithm 18 shown above, for the case where the estimated temperature is above thermal limit, also includes a summation term (which also includes the constant scaling factor beta). This summation or integral of the excessᵢ values (up to N prior samples) acts, in effect, to increase the attenuation, so long as the summation of the excess, values is positive. This may help reduce the likelihood or the severity of overshoot of the estimated temperature (above the thermal limit). Such an overshoot can be seen, for instance in FIG. 3, which shows a simulation of an embodiment of the invention. FIG. 3 also shows the relatively dramatic reduction in gain (increase in attenuation) that occurs due to the detected overshoot in the predicted temperature. The simulation is, of course, for an example audio signal, in this case being a 15 kHz sine wave, although it is expected that similar behavior may be produced at other audio frequency ranges.

Returning to the control algorithm 18 shown above, if the estimated temperature is not higher than the thermal limit but is higher than a soft limit, that is, it lies within the soft limit range (see FIG. 6), where in this case the soft limit is defined as being 80% of the thermal limit, then the gain is again given by a square root function of the excess, except that here (1) the current sample of excess is negative, and (2) there may be no contribution from the summation term (involving previous samples of excess). This may yield a larger gain (smaller attenuation) than when the estimated temperature is above the thermal limit. The gain computation here includes the constants K₃ and K₄, which should be selected, during laboratory testing, to yield the desired temperature behavior in the soft limit range. In one embodiment K₃=1 and K₄=0.25.

In accordance with a second version of the thermal control algorithm 18, the following modification is made to the first version described above. This modification is useful when the estimated temperature is oscillating between above the thermal limit and into the soft limit range, in order to maintain smooth gain modification, particularly in a scenario similar to that depicted in FIG. 6. When the estimated temperature transitions downward into the soft limit range, the summation term is retained in the equation for gain (even though the estimated temperature now lies in the soft limit range). Now however, the current sample of the variable excess is a negative value, which is now included in the summation. Thus, referring now to the example in FIG. 6, when the gain update is calculated at t₂, the summation elements include excess₁+excess₂. At the next update, namely at t3, the summation elements include excess₁+excess₂+excess₃. The updates continue in this way until the summation term reaches essentially zero (or is “disabled”), which means the gain equation becomes similar to

$$gain = \sqrt{{K}_{1} - {K}_{2} * \frac{excess}{soft\_limit \_range}}$$

Next, the summation term remains disabled as gain updates continue to be calculated, until the estimated temperature rises above the thermal limit at which point the gain equation reverts back to its original form that contains the summation term. As an example of this modification, consider the following sequence of downwardly trending temperature estimates: 105, 102, 101, 100; at the last sample (100), and assuming a thermal limit of 100, the summation/integral of excess would be 8; if the next estimated temperature in the sequence is 99, then the summation term becomes 7.

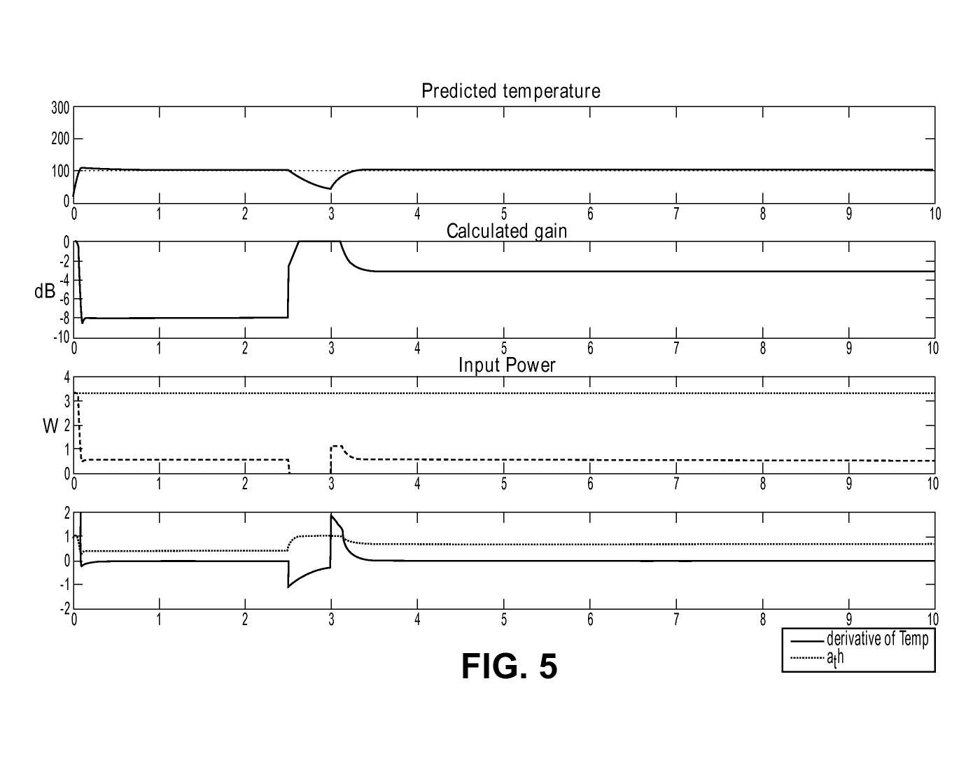

In accordance with a third version of the thermal control algorithm 18, the following modification is made to the first version described above. This modification is useful when it appears that the estimated temperature is settling within the soft limit range (rather than moving climbing above the thermal limit). Here, if the derivative of the estimated temperature is below a given threshold (see FIG. 5 for an example plot showing the predicted temperature, the resulting calculated gain, and the derivative of the predicated temperature), or in other words the estimated temperature has not changed too drastically, then the attenuation is slowly reduced (or gain is slowly added back) towards 0 dB. This is done so as to not unnecessarily attenuate the audio signal, since the speaker is clearly operating below its thermal limit. To achieve this result, the following change may be made to the original gain equation above:

$$gain = \sqrt{{K}_{1} - {K}_{2} * \frac{excess}{soft\_limit \_range}} + accum\_factor$$

where accum_factor represents an accumulation that is to grow each sampling period so long as the absolute value of the temperature derivative is relatively small. In other words, this update for the gain equation is repeated so long as the derivative is smaller than K₆; for instance,

if abs(derivative(estimated_temp))<K₆

then accum_factor=accum_factor+K₅

end if

where K₅ would be a small number that may be determined empirically, perhaps decreasing as estimated_temp approaches the thermal limit (and thus may not be constant). K₅ and K₆ can be tuned through experimentation so as to remove unnecessary attenuation when the estimated temperature settles in the soft limit range.

As explained above, an embodiment of the invention may be a machine-readable medium (such as microelectronic memory) having stored thereon instructions, which program one or more data processing components (generically referred to here as a “processor”) to perform digital audio processing and a thermal control algorithm as described above, including audio signal attenuation, arithmetic such as addition, subtraction, and comparison, and square root calculations. In other embodiments, some of these operations might be performed by specific hardware components that contain hardwired logic (e.g., dedicated digital filter blocks). Those operations might alternatively be performed by any combination of programmed data processing components and fixed hardwired circuit components.

While certain embodiments have been described and shown in the accompanying drawings, it is to be understood that such embodiments are merely illustrative of and not restrictive on the broad invention, and that the invention is not limited to the specific constructions and arrangements shown and described, since various other modifications may occur to those of ordinary skill in the art. For example, in one embodiment, the gain stage 12_N attenuates its input audio signal by applying a scaling factor to the input audio discrete time sequence, that is in the time domain; an alternative may be to apply the scaling factor only to a specific sub-band, that is in the frequency domain, of the input audio sequence. The description is thus to be regarded as illustrative instead of limiting.

What is claimed is:

1. A method for controlling an audio signal that is driving a speaker, comprising:
a. computing a sequence of estimated temperatures using a speaker thermal model, as a function of an audio signal that is driving a speaker;
b. computing a sequence of attenuation values as a function of the estimated temperatures sequence, using an excess variable that is defined as a difference between an estimated temperature and a thermal limit of the speaker; and
c. attenuating the audio signal in accordance with the sequence of attenuation values.

2. The method of claim 1 wherein computing a sequence of attenuation values comprises computing a square root of a polynomial in the excess variable.

3. The method of claim 2, wherein computing a sequence of attenuation values further comprises computing a summation of a plurality of prior samples of the excess variable.

4. The method of any one of claims 1 wherein the excess variable is positive when the estimated temperature is greater than the thermal limit, and negative when the estimate temperature is smaller than the thermal limit.

5. The method of any one of claims 1 wherein the attenuation values are essentially zero when the estimated temperatures are below a soft limit range which is below the thermal limit.

6. An audio device comprising:
a. an attenuator to attenuate an audio signal that is to then drive a speaker having a thermal limit; and
b. a thermal control module coupled to control the attenuator, the thermal control module to compute a sequence of estimated temperatures of the speaker, based on the audio signal, and to compute a sequence of attenuation settings for the attenuator, wherein each of the attenuation settings is computed based on computing the summation of a plurality of prior samples of an excess variable, each of the prior samples of the excess variable being a difference between (a) a then current sample of the sequence of estimated temperatures and (b) the thermal limit of the speaker.

7. The audio device of claim 6 wherein the thermal control module computes the sequence of attenuation settings using the summation, both when the sequence of estimated temperatures are higher than the thermal limit and when the sequence of estimated temperatures are lower than the thermal limit but within a soft limit range.

8. The audio device of claim 6 wherein the thermal control module is to compute the sequence of attenuation settings using a square root of a polynomial in the excess variable.

9. The audio device of claim 6 wherein the excess variable is positive when the estimated temperature is greater than the thermal limit, and negative when the estimate temperature is smaller than the thermal limit.

10. The audio device of claim 9 wherein the attenuation settings are essentially zero when the estimated temperatures are below a soft limit range which is below the thermal limit.

11. An article of manufacture comprising:
a machine-readable medium having stored therein instructions that program a processor to compute a sequence of estimated temperatures based on an audio signal that is driving a speaker, and to compute a sequence of attenuation settings for attenuating the audio signal that is driving the speaker, wherein each of the attenuation settings is computed as a function of the summation of a plurality of prior samples of an excess variable wherein each of the prior samples is a difference between (a) a then current sample of the sequence of estimated temperatures and (b) the thermal limit of the speaker.

12. The article of manufacture of claim 11 wherein the instructions are such that the sequence of attenuation settings are computed using the summation, both when the sequence of estimated temperatures are higher than the thermal limit and when the sequence of estimated temperatures are lower than the thermal limit but within a soft limit range.

13. The article of manufacture of claim 11 wherein the instructions are such that the sequence of attenuation settings are computed using a square root of a polynomial in the excess variable.

14. The article of manufacture of claim 12 wherein the excess variable is positive when the estimated temperature is greater than the thermal limit, and negative when the estimate temperature is smaller than the thermal limit.

15. The article of manufacture of claim 12 wherein the attenuation settings are essentially zero when the estimated temperatures are below a soft limit range which is below the thermal limit.
